(19) United States
(12) Patent Application Publication
(10) Pub. No.: US 2019/0301011 A1
(43) Pub. Date: Oct. 3, 2019

(54) LOW TEMPERATURE IN-SITU CLEANING METHOD FOR EPI-CHAMBERS

(71) Applicant: Applied Materials, Inc., Santa Clara, CA (US)

(72) Inventors: Geetika BAJAJ, New Delhi (IN); Prerna Sonthalia GORADIA, Mumbai (IN); Robert Jan VISSER, Menlo Park, CA (US); Abhishek DUBE, Fremont, CA (US); Flora Fong-Song CHANG, Saratoga, CA (US); Hua CHUNG, San Jose, CA (US)

(21) Appl. No.: 16/366,570

(22) Filed: Mar. 27, 2019

Related U.S. Application Data
(60) Provisional application No. 62/650,282, filed on Mar. 30, 2018.

(51) Int. Cl. C23C 16/44; C23C 16/52; C23C 16/48

(52) U.S. Cl. CPC C23C 16/4405; C23C 16/52; C23C 16/4488; C23C 16/4411; C23C 16/482

(57) ABSTRACT

Embodiments of the disclosure may provide a method and apparatus for cleaning an epi-chamber at a low temperature so that residues are quickly eliminated from a surface of the epi-chamber after a performing a low temperature epitaxial deposition process. Some of the benefits of the present disclosure include flowing a chlorine containing gas to an improved epi-chamber having UV capability to chlorinate and quickly remove the epitaxial deposition residues at a low cleaning process temperature. As such, residues are decreased or removed from the epi-chamber such that further processing may be performed.

### CROSS-REFERENCE TO RELATED APPLICATIONS

This application claims priority under 35 U.S.C. § 119 (e) to U.S. Provisional Application No. 62/650,282, filed Mar. 30, 2018, which is incorporated by reference herein.

### BACKGROUND

### Field

Embodiments of the present disclosure generally relate to apparatus and methods for performing a low temperature in-situ cleaning of an epi-chamber.

### Description of the Related Art

Epitaxial deposition processes are commonly used for depositing various semiconductor device structures. For example, the source and drain regions of a fin field effect transistor (FinFET) may be deposited via epitaxial processes. Typically, epitaxial deposition processes of silicon device structures utilizes vapor deposition of an halogen containing gas such as hydrogen chloride (HCl) and chlorine (Cl₂) and a silicon source gas such as silane (SiH₄) and dichlorosilane (SiH₂Cl₂) in an epitaxial deposition chamber (also referred to as an epi-chamber) having an inner surface of quartz and/or other ceramic materials such as SiC at a high temperature between about 700° C. and about 1200° C. During such an epitaxial deposition process, byproducts that contain silicon may be subsequently deposited on the inner surface of the chamber. Prior to a subsequent epitaxial deposition process, the epi-chamber is normally cleaned with hydrogen chloride (HCl) or diluted chlorine (Cl₂) gas flow. The cleaning is generally performed at temperatures as high as 1000-1200° C. with HCl and at 700-900° C. with Cl₂ to dissociate silicon from the inner surface of the chamber. However, cleaning processes that use Cl₂ will cause metal contamination issues. Specifically, at lower process temperatures, such as less than about 550° C., iron (Fe) will be extracted from conventional chamber components, which are used as the inner surface of the epi-chamber, and/or stainless steel gas delivery components leading to iron contamination in the deposited epitaxial films formed in the epi-chamber.

As industry roadmap requires process temperatures for epitaxial deposition of silicon devices to be lower, typically lower than 550° C., there is a need for improved methods for cleaning a chamber at low temperatures to reduce an overhead time that is currently required in conventional cleaning processes to heat-up the chamber to a higher cleaning process temperature and then cool the chamber back down to its lower epi-deposition temperature. Furthermore, cleaning a chamber at low temperatures reduces a stress on the quartz or ceramic chamber components often used in the epi-chambers.

### SUMMARY

Embodiments of the disclosure may include a method of cleaning an epitaxial deposition chamber by removing all substrates from the epitaxial deposition chamber, maintaining a temperature of the epitaxial deposition chamber at less than about 550° C., flowing a chlorine-containing gas into the epitaxial deposition chamber through a gas line of the epitaxial deposition chamber, flowing a purge gas into the epitaxial deposition chamber through the gas line of the epitaxial deposition chamber, activating a UV lamp module to chlorinate residues on a surface of the epitaxial deposition chamber to form a chlorinated layer on the surface of the epitaxial deposition chamber, ceasing the flow of the chlorine-containing gas and the purge gas into the epitaxial deposition chamber, pumping gases from the epitaxial deposition chamber, and deactivating the UV lamp module.

Embodiments of the disclosure may also include an epi-chamber that includes a top ceiling and a chamber wall defining a processing volume therein, a substrate support disposed within the processing volume, a quartz window disposed at the top ceiling, a UV lamp module disposed above the quartz window, a cooling fan disposed above the UV lamp module, a vacuum pump coupled to the chamber wall through an exhaust port, and a gas source in fluid communication with a gas line extending through the chamber wall.

### BRIEF DESCRIPTION OF THE DRAWINGS

So that the manner in which the above recited features of the disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a schematic flow diagram of a method for cleaning of an epi-chamber.

FIG. 2 schematically illustrates a side cross-sectional view of an epi-chamber according to implementations of the present disclosure.

FIG. 3 illustrates a cross-sectional schematic view of a portion of a UV lamp module in accordance with one implementation of the present disclosure.

FIG. 4 illustrates a top view of a portion of a UV lamp module in accordance with another implementation of the present disclosure.

To facilitate understanding, identical reference numerals have been used, where possible, to designate identical elements that are common to the figures. It is contemplated that elements disclosed in one implementation may be beneficially utilized on other implementations without specific recitation.

### DETAILED DESCRIPTION

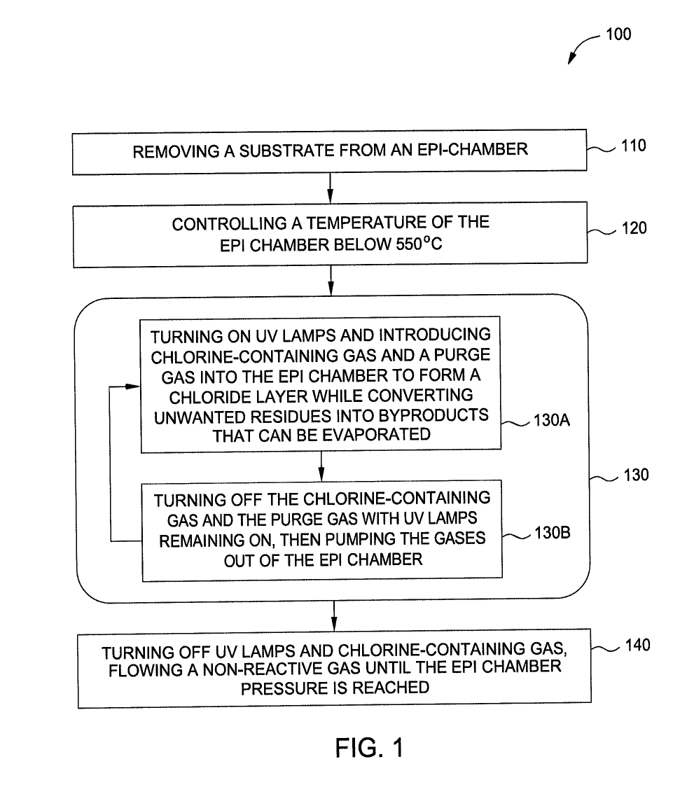

FIG. 1 is a schematic flow diagram of a method 100 for cleaning of an epitaxial deposition chamber. The method 100 provides methods for cleaning at a low temperature. Epitaxial deposition chamber cleaning generally relates to the removal of an unwanted deposition materials from internal surfaces of the epitaxial deposition chamber after one or more epitaxial deposition processes have been performed therein. Epitaxial deposition chamber cleaning relates to reducing and/or eliminating residual unwanted materials, for example, silicon containing byproducts of an epitaxial deposition process, from a passivation chamber prior to subsequent epitaxial deposition processes.

A “substrate” or “substrate surface,” as described herein, generally refers to any substrate surface upon which processing is performed. For example, a substrate surface may include materials that include silicon, silicon oxide, doped silicon, silicon germanium, germanium, gallium arsenide, glass, sapphire, and any other materials, such as metals, metal nitrides, metal alloys, and other conductive or semi-conductive materials, depending on the application. A substrate or substrate surface may also include dielectric materials such as silicon dioxide, silicon nitride, organosilicates, and carbon doped silicon oxide or nitride materials. The term “substrate” may further include the term “wafer.” The substrate itself is not limited to any particular size or shape. Although the implementations described herein are generally made with reference to a round substrate, other shapes, such as polygonal, squared, rectangular, curved, or otherwise non-circular workpieces may be utilized according to the implementations described herein.

At operation 110 in FIG. 1, a substrate is removed from an epitaxial deposition chamber (also referred to as an epi-chamber) after an epitaxial deposition process has been performed on a substrate, wherein thereafter a cleaning process is performed to remove residues remaining on a surface of the epi-chamber from the prior epitaxial deposition processes.

Any suitable epitaxial deposition process may be performed in the epi-chamber. The epitaxial deposition may be a selective epitaxial deposition process. The epitaxial layer may be a doped or an undoped group IV-containing material such as Si, Si:P, SiGe, SiC, SiAs, SiGe:B, Si:CP, or any suitable semiconductor materials or compound semiconductor materials such as group III-V semiconductor compound materials. In one implementation, the epitaxial layer is an n-type doped silicon layer, for example a silicon layer doped with arsenic (Si:As) or a silicon layer doped with phosphorus (Si:P).

In one implementation, the epitaxial layer is deposited using a high or moderate temperature chemical vapor deposition (CVD) process. In one embodiment, the epitaxial deposition process is used to deposit a silicon containing film layer at a temperature less than or equal to 550° C. In this thermal-CVD process, processing gases such as dichlorosilane, silane, disilane, germane, phosphorus-containing gas, arsenic-containing gas, hydrogen chloride, or combinations thereof are used to deposit the epitaxial layer.

Optionally, in another embodiment, the epitaxial deposition process may be replaced by the Group III-V deposition process, depending on the application.

The residues include byproducts of the epitaxial deposition processes such as silicon phosphide (SiP). A thickness of the residues may be at a range of between about 500 Å and about 600 Å, or may be at about 1 nm.

At operation 120, once the substrate has been removed from the epi-chamber, a temperature of the epi-chamber is controlled and stabilized. Any suitable methods for controlling the temperature may be used, such as closed loop control of the power delivered to one or more radiant lamps. In one implementation, the temperature of the epi-chamber may be controlled by flowing or by circulating a cooling fluid or a cooling gas through the epi-chamber's processing region or a portion of the supporting structure of the epi-chamber, and/or controlled by use of a closed loop control of power delivered to one or more radiant lamps.

During the cleaning processes described herein, the epi-chamber may be maintained at a temperature below about 550° C., preferably within an approximate temperature range of between about 100° C. and about 500° C., such as a temperature between about 150° C. and about 500° C., or a temperature between about 150° C. and about 350° C.

The operation 130 generally includes a UV activation process 130A and a purging process 130B. The UV activation process 130A and the purging process 130B may be alternatingly performed to form a chlorinated layer on the residues while removing unwanted species that are loosely bonded on the surface of the epi-chamber. For example, if the residues contain silicon, these silicon-containing species are chlorinated by the UV activation process 130A to form a monolayer of silicon monochloride (SiCl). At the same time, silicon-containing species are partially desorbed and converted to high vapor pressure byproducts due to the chlorination of the surface of the exposed material within the epi-chamber, which are then pumped out of the epi-chamber during the purging process 130B. The UV activation process 130A and the purging process 130B may be repeated multiple times until outgassing of unwanted species, for example, silicon containing species, is undetectable.

During the UV activation process 130A, UV lamps or bulbs are activated to provide electromagnetic energy to the process gases and surface of the chamber. The exposed process gases may include a chlorine-containing gas and a non-reactive purge gas that are introduced into the epitaxial deposition chamber. Suitable purge gases include argon, helium, hydrogen, nitrogen, or mixtures thereof. The UV lamps may be activated before, during, or after flowing of the chlorine-containing gas and the purge-containing gas into the epi-chamber. The UV radiation is used to dissociate the chlorine-containing gas into Cl₂ or Cl radicals which chlorinate the silicon-containing residues to form a chlorinated layer on the surface of the epi-chamber. The UV radiation also causes the exposed deposition residues to convert into vaporizable byproducts that are at least partially removed out of the epi-chamber during the purging process 130B. By “UV radiation” is meant radiation having a wavelength generally in the range of 100 nm to 400 nm. In some embodiments, by “UVA radiation” is meant radiation having a wavelength generally in the range of 250 nm to 400 nm.

In some implementations, the flow of the purge gas is ceased and the epi-chamber is exposed only to the chlorine-containing gas during the UV activation process 130A. Suitable chlorine-containing gases may include chlorine (Cl₂), hydrogen chloride (HCl), or any combination thereof. Chlorine containing gases can be further diluted with inert gases like argon or with nitrogen.

The wavelength of the UV lamps may be selected to activate or dissociate the chlorine-containing gas. For example, the chlorine-containing gas may be exposed to UV radiation at a range of between about 10 nm and about 500 nm, for example between about 190 nm and 365 nm. Example wavelengths are 193 nm, 248 nm, 266 nm, 290 nm, 355 nm, 365 nm, and 420 nm. In one embodiment, the UV radiation is provided from a specific UV emission source or a broad band radiation source that is filtered to provide radiation in a specific range of 250 nm to 400 nm, such as range of 300 nm to 375 nm. If chlorine is used during the UV activation process 130A, wavelengths between about 275 nm and about 500 nm may be used because diatomic chlorine has been found to absorb wavelengths between 250 nm and 400 nm. If hydrogen chloride is used during the UV activation process 130A, wavelengths between 266 nm and about 290 nm may be used because hydrogen chloride absorbs the 253.7 nm wavelength. In some implementations, the UV lamps may emit two different wavelengths to enhance dissociation of the gases, species or residues. For example, a first set of UV lamps are configured to emit a first UV radiation of about 240 nm and a second set of UV lamps are configured to emit a second UV radiation of about 355 nm. The UV radiation may be delivered at intensity between 0.05 and 60 mW/cm², for example, 15 mW/cm², or between 0.05 and 5 W/cm².

The UV activation process 130A may be performed for about 5 seconds to about 2 minute depending upon the thickness of film to be removed, for example about 10 seconds to about 30 seconds. The chamber pressure during the UV activation process 130A may be maintained at an pressure of between 0.1 Torr and 760 Torr, such a pressure between about 100 milliTorr (mTorr) and about 100 Torr, such as a pressure of about 140 mTorr and 700 mTorr, or a pressure of about 250 and 680 mTorr, or a pressure of about 450 and 680 mTorr.

During the purging process 130B, flowing of the chlorine-containing gas and the purge gas is stopped, and the chlorine-containing gas and the purge gas are pumped out of the epi-chamber. The UV lamps may remain on or be deactivated during the purging process 130B. In some implementations, the UV lamps remain on during the purging process 130B. The chamber pressure may be controlled from an epi-deposition process pressure (e.g., 80 Torr) to a lower pressure of about 0.1 Torr to about 20 Torr, for example about 1 Torr. The purging process 130B may be performed for about 10 seconds to about 40 seconds, such as about 15 seconds to about 30 seconds, for example about 20 seconds.

Once the chlorine-containing gas and the purge gas have been pumped out of the epi-chamber, the UV activation process 130A described above may be repeated. For example, flowing of the chlorine-containing gas and the purge gas is resumed and the UV lamps or bulbs are activated (if previously deactivated) to dissociate the chlorine-containing gas into Cl₂ or CI radicals which again chlorinate the exposed material on the surface of the epi-chamber, such as a silicon-containing species to form a monolayer of silicon monochloride (SiCl) on the surface of the epi-chamber, while breaking the bonds formed between the unwanted species and the surface of the epi-chamber and/or reacting with the residues to convert them into byproducts that can be evaporated quickly and removed out of the epi-chamber during the purging process 130B. The UV activation process 130A may be performed for about 5 seconds to about 45 seconds, for example about 10 seconds to about 30 seconds.

Thereafter, the purging process 130B described above may be repeated. For example, flowing of the chlorine-containing gas and the purge gas are deactivated, with or without the UV lamps activated, and the chlorine-containing gas and the purge gas are pumped out of the epi-chamber. The chamber pressure is again changed from the UV activation process 130A pressure to a different purging process 130B pressure, such as described above. The purging process 130B may be performed for about 10 seconds to about 40 seconds, such as about 15 seconds to about 30 seconds, for example about 20 seconds.

The UV activation process 130A and the purging process 130B may be repeated from 2 to 20 cycles or more until unwanted species are removed from the epi-chamber. In various implementations, the UV activation process 130A and the purging process 130B are repeated for about 2 to about 50 cycles, such as about 2 to 5 cycles, or about 5 to 10 cycles, or about 10 to 15 cycles, or about 15 to 20 cycles.

At operation 140, once the unwanted species have been removed from the surface of the epi-chamber (i.e., no detectable outgassing of toxic species), the UV lamps are deactivated and flowing of the chlorine-containing gas is deactivated. The purge gas may continue flowing or may be resumed (if previously deactivated) or a non-reactive gas such as nitrogen gas may be flowed into the epi-chamber until a desirable pressure is reached in the epi-chamber, such as the epitaxial deposition process pressure (e.g., 80 Torr). In one implementation, the purge gas is flowed into the epi-chamber for about 20 seconds or less, for example about 15 seconds or less, for example 12 seconds or less, such as about 5 seconds to about 10 seconds. Other non-reactive gas may also be used alternatively or in addition to the purge gas.

Once the desired pressure is reached within the epi-chamber, a new substrate may be transferred into the epi-chamber for a subsequent epitaxial deposition process. One or more of the operations 120-140 described herein may be completed after every epitaxial deposition process is performed in the epi-chamber, or alternately after two or more of the deposition processes are sequentially performed in the epi-chamber. Operations 120-140 may additionally or separately be completed during times when the epi-chamber is idle, or before or after maintenance activities are performed.

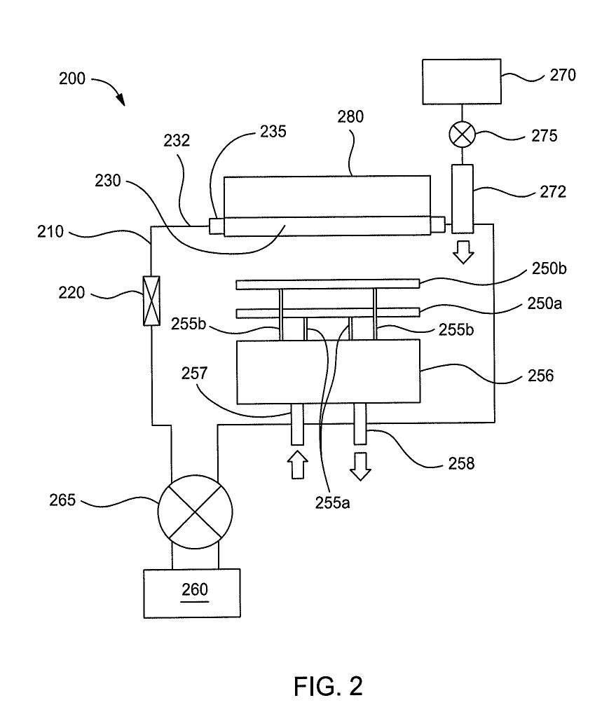

As will be discussed in further detail below with respect to FIG. 2, the epi-chamber is an improved chamber having an ultraviolet (UV) lamp module disposed adjacent to a top ceiling of the chamber for cleaning after an epitaxial deposition process. It should be appreciated that the operations 110-140 may be performed by the epi-chamber 200 shown in FIG. 2 or any other chamber function similarly or equally to the epi-chamber 200.

FIG. 2 schematically illustrates a simplified side cross-sectional view of an epi-chamber 200 according to implementations of the present disclosure. The epi-chamber may be used to perform the operation 130, such as the UV activation process 130A and the purging process 130B discussed above with respect to FIG. 1. The epi-chamber 200 comprises a chamber wall 210, which may be made of a metallic material such as aluminum. The chamber wall 210 defines a processing volume therein. A quartz window 230 is clamped to a top ceiling 232 of the chamber wall 210. The quartz window 230 may be made of synthetic quartz for its high transmission of UV light. A continuous O-ring 235 may be disposed between the quartz window 230 and the chamber wall 210 to provide a vacuum seal. A UV lamp module 280 may be disposed above the quartz window 230, with or without a gap between the UV lamp module 280 and the quartz window 230. A vacuum pump 260 is connected to the epi-chamber 200 through an exhaust port which can be closed by a valve 265. The vacuum pump 260 evacuates the epi-chamber 200 to a certain vacuum level suitable for the purging process 130B discussed above. A gas source 270, which may include a chlorine-containing gas source and a purge gas source as discussed above with respect to FIG. 1, is connected to the epi-chamber 200 through a gas line 272, which can be closed by a gas valve 275.

While a single gas line 272 is shown, it is contemplated that two or more gas lines may be adapted for flowing of same or different gases. In some implementations, two gas lines may be disposed at the top ceiling 232 of the epi-chamber 200. Additionally or alternatively, one or more gas lines may be disposed at the sidewall of the epi-chamber 200. Each of the gas lines may be configured to flow one or more processing gases as discussed above at operation 130.

The quartz window 230 is configured to be mounted on the top ceiling 232 of the epi-chamber 200 in which UV light from the UV lamp module 280 is transmitted through the quartz window 230 while a gas such as a chlorine-containing gas and a purge gas is flowed into the epi-chamber 200 to perform processes, such as the UV activation process 130A discussed above at operation 130.

A plurality of substrates, for example, two substrates 250a, 250b, may be lifted and supported respectively by a plurality of substrate support pins 255a, 255b extending upwardly from the substrate support 156. The temperature of the substrate support 256 may be adjusted by circulating a cooling fluid or a cooling gas from an inlet 257 through the substrate support 256 to an outlet 258.

Prior to an epitaxial deposition process, the substrates, for example, the substrates 250a, 250b are transferred through a loading port 220 in the chamber wall 210 and placed on the substrate support pins 255a, 255b, respectively. The epi-chamber 200 may be evacuated by the vacuum pump 260 to reach the epi-chamber before the substrates are loaded into the epi-chamber 200. During the UV activation process 130A, the UV lamp module 280 is activated once the substrates are removed from the epi-chamber, and a chlorine-containing gas and a purge gas from the gas source 270 are introduced into the epi-chamber 200 through the gas line 272. The UV lamp module 280 may be activated before, during, or after flowing of the chlorine-containing gas and the purge gas into the epi-chamber 200. The UV lamp module 280 irradiates the chamber wall 210 of the epi-chamber through the quartz window 230 with UV radiation at a wavelength of 240 nm and intensity between 0.05 and 5 W/cm², for about 10 seconds to about 30 seconds. The chlorine-containing gas absorbs UV radiation and decomposes into Cl or Cl₂ radicals which react with the unwanted residue, for example silicon-containing byproducts and arsenic-containing species, to form silicon chloride and arsenic chloride on the surface of the chamber wall 210. As discussed previously, some of the unwanted residues or species are converted into byproducts that can be evaporated quickly. At the same time, the Cl or Cl₂ radicals also break the loose bonds between the unwanted species and the surface of the epi-chamber 200, thereby removing silicon-containing residues absorbed or trapped on the surface of the epi-chamber 200. The reaction products are gaseous and can be evacuated from the epi-chamber 200 by the vacuum pump 260, as the purging process 130B discussed above with respect to FIG. 1.

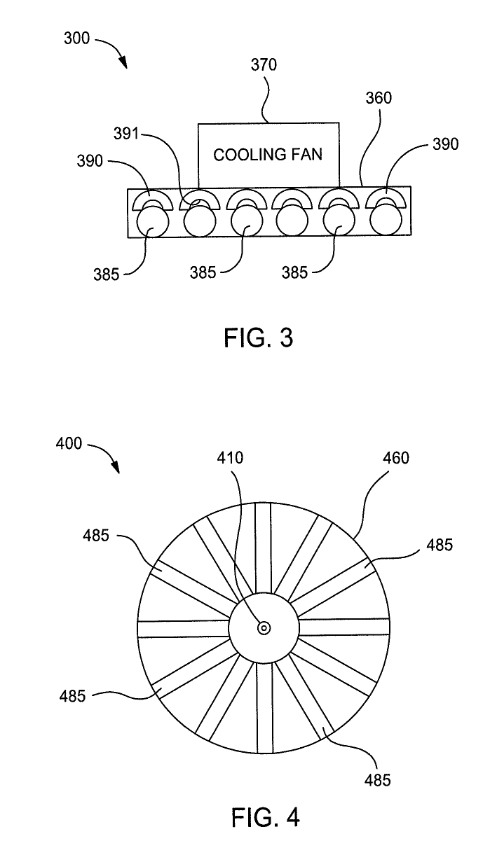

The UV lamp module 280 may have different configurations to enhance efficiency of the chlorination process. FIG. 3 illustrates a cross-sectional schematic view of a portion of a UV lamp module 300 in accordance with one implementation of the present disclosure. The UV lamp module 300 may be used in place of the UV lamp module 280. The UV lamp module 300 generally includes a housing 360 for holding a plurality of UV lamps 385 therein. The UV lamps 385 can be arranged parallel with each other and sized to cover substantially the entire area of the quartz window 230 (FIG. 2) to achieve uniform UV radiation intensity above the substrate, such as the substrates 250A, 250B in the epi-chamber 200. The UV lamps 385 may have identical or different lengths sized to overlay the quartz window 230. In one implementation, the UV lamps 385 are arranged in two columns disposed either head to head or offset from each other. In such a case, the first column of UV lamps and the second column of UV lamps may be configured co-planar. The UV lamps 385 may have a square design, while other shape such as a round shape is also contemplated.

A single hollow, half-spherical reflector 390 surrounds each UV lamp 385. Each UV lamp 385 may have a tubular shape, a dual-tubular shape or other suitable shape. The reflectors 390 are arranged above the UV lamps 385 and the UV radiation from the UV lamps 385 can pass directly through the quartz window 230 into the epi-chamber 200. The spherical or concave surface 391 of each reflector 390 reflects UV radiation downward to enhance intensity and uniformity of the UV radiation. The reflectors 390 may have a constant thickness of about 1 mm to about 5 mm to provide the needed mechanical strength. While a half-spherical reflector 390 is shown, other shapes such as oval or upside-down V shape are also contemplated.

If desired, the reflectors 390 may have a reflective coating layer or layer stack provided on the underside (i.e., facing the UV lamp 385) of the reflector 390. The reflective coating layer or layer stack is designed to reflect or direct UV radiation to the substrates. In one implementation, the reflective coating layer is a multi-layer coating having at least two materials of different refractive index, which in combination reflect radiation in the UV range of the electromagnetic spectrum. Suitable materials for the multi-layer coating may include at least one of the oxides or nitrides of aluminum, tantalum, titanium, silicon, niobium, hafnium, cerium, zirconium, yttrium, erbium, europium, gadolinium, indium, magnesium, bismuth, thorium, and combinations thereof and similarly suitable rare earth metals. In one implementation, the multi-layer coating includes a combination of at least two of the above oxides or nitrides.

A cooling fan 370 may be mounted on the upper surface of the housing 360. When powered, the cooling fan 370 will draw air from the top, through an opening (not shown) located at the bottom of the cooling fan 370 to cool the reflectors 390 within the housing 360. The cooling of the reflectors 390 cools the UV lamps 385 as well.

FIG. 4 illustrates a top view of a portion of a UV lamp module 400 in accordance with another implementation of the present disclosure. The UV lamp module 400 may be used in place of the UV lamp module 280. In this implementation, a plurality of UV lamps 485 are disposed or housed within a housing 460. The UV lamps 485 may have a tubular shape, a dual-tubular shape or other suitable shape. The UV lamps 485 extend radially outward (e.g., like spokes of a wheel) from a central axis 410 of the housing 460. The UV lamps 485 may be equally spaced around the outer circumference of the housing 460 to provide uniform irradiation of the substrates 250A, 250B (FIG. 2).

While not shown, a single hollow, half-spherical reflector, such as the reflector 390 discussed above, may be used to surround each UV lamp 485 to reflect or direct UV radiation to the substrates.

The UV lamps 385 and the UV lamps 485 are arranged so UV that radiation is emitted in a way such that the entire substrate surface is irradiated uniformly, while all molecules of the processing gases within the epi-chamber 200, from top to bottom and side to side, are saturated with UV radiation flux.

Test results indicate that after an exposure to a chlorine containing gas and UV radiation, a layer of amorphous silicon (a-Si) having a thickness of 70 nm on a substrate is completely removed from the chamber surface at temperatures of 170° C., 250° C., and 350° C. depending on the UV activation process 130A process pressures. In one example, the UV activation process 130A is performed at a pressure of between 480 and 680 mTorr and a temperature of about 170° C. to about 250° C. In another example, the UV activation process 130A is performed at a pressure of between 145 and 680 mTorr and a temperature of about 250° C. and about 350° C.

To summarize, the implementations disclosed herein relate to methods and apparatuses for cleaning an epi-chamber at a low temperature such that residues are quickly eliminated from a surface of the epi-chamber after an epitaxial deposition process, and prior to additional processing. Some of the benefits of the present disclosure include flowing chlorine containing gas to an improved epi-chamber having UV capability to chlorinate silicon-containing residues and quickly removing the residues at a low temperature. As such, residues are decreased and/or removed from the epi-chamber such that further processing may be performed.

While the foregoing is directed to implementations of the present disclosure, other and further implementations of the disclosure may be devised without departing from the basic scope thereof, and the scope thereof is determined by the claims that follow.

What is claimed is:

1. A method of cleaning an epi-chamber, comprising:
removing all substrates from the epi-chamber;
maintaining a temperature of the epi-chamber at less than about 550° C.;
flowing a chlorine-containing gas into the epi-chamber through a gas line of the epi-chamber;
flowing a purge gas into the epi-chamber through the gas line of the epi-chamber;
activating a UV lamp module to chlorinate residues on a surface of the epi-chamber to form a chlorinated layer on the surface of the epi-chamber;
ceasing the flow of the chlorine-containing gas and the purge gas into the epi-chamber;
pumping gases from the epi-chamber; and
deactivating the UV lamp module.

2. The method of claim 1, further comprising:
repeating for about 2 to 5 cycles the flowing a chlorine-containing gas into the epi-chamber through the gas line of the epi-chamber, the flowing a purge gas into the epi-chamber through the gas line of the epi-chamber, the activating a UV lamp module to chlorinate residues on the surface of the epi-chamber to form a chlorinated layer on the surface of the epi-chamber, the ceasing the flow of the chlorine-containing gas and the purge gas into the epi-chamber, and the pumping the epi-chamber.

3. The method of claim 2, wherein the residues contain silicon.

4. The method of claim 2, wherein the activating a UV lamp module to chlorinate the residues on the surface of the epi-chamber is performed for about 5 seconds to about 2 minutes.

5. The method of claim 1, further comprising:
between the ceasing the flowing of the chlorine-containing gas and the purge gas into the epi-chamber and the pumping the epi-chamber, flowing a non-reactive gas into the epi-chamber.

6. The method of claim 1, further comprising:
after the deactivating the UV lamp module, flowing a purge gas into the epi-chamber, wherein a pressure of the epi-chamber is maintained at about 100 milliTorr to about 100 Torr.

7. The method of claim 1, wherein a pressure of the epi-chamber is maintained at about 100 milliTorr to about 100 Torr during the activating the UV lamp module to chlorinate residues on the surface of the epi-chamber.

8. The method of claim 1, wherein during the pumping the epi-chamber a pressure of the epi-chamber is maintained at about 1 Torr.

9. The method of claim 1, wherein the UV lamp module emits radiation having a wavelength in a range of 100 nm to 400 nm.

10. The method of claim 1, wherein the pumping the epi-chamber is performed for about 20 seconds.

11. The method of claim 1, wherein the UV lamp module comprises a plurality of UV lamps, each UV lamp of the plurality being arranged in a first direction.

12. The method of claim 11, wherein each of the UV lamps has a reflector disposed above the plurality of UV lamps to direct UV radiation to the substrates.

13. The method of claim 12, wherein the reflector has a reflective coating layer comprising a material selected from the group consisting of oxides and nitrides of aluminum, tantalum, titanium, silicon, niobium, hafnium, cerium, zirconium, yttrium, erbium, europium, gadolinium, indium, magnesium, bismuth, and thorium, and combinations thereof.

14. The method of claim 11, wherein the UV lamps are arranged in a square shape.

15. The method of claim 1, wherein the UV lamp module comprises a plurality of UV lamps disposed within a housing, and the plurality of UV lamps extend radially outward from a central axis of the housing.

16. An epi-chamber, comprising:
a top ceiling and a chamber wall defining a processing volume therein;
a substrate support disposed within the processing volume;
a quartz window disposed at the top ceiling;
a UV lamp module disposed above the quartz window;
a cooling fan disposed above the UV lamp module;
a vacuum pump coupled to the chamber wall through an exhaust port; and
a gas source in fluid communication with a gas line extending through the chamber wall.

17. The epi-chamber of claim 16, wherein the UV lamp module comprises a plurality of UV lamps.

18. The epi-chamber of claim 17, wherein each of the UV lamps has a reflector disposed above the plurality of UV lamps to direct UV radiation to the substrate support.

19. The epi-chamber of claim 17, wherein each UV lamp of the plurality of UV lamps is arranged in a first direction.

20. The epi-chamber of claim 17, wherein the plurality of UV lamps are disposed within a housing, and the plurality of UV lamps extend radially outward from a central axis of the housing.
